(19) United States
(12) Patent Application Publication
(10) Pub. No.: US 2005/0070040 A1
(43) Pub. Date: Mar. 31, 2005

(54) Surface acoustic wave element and method for fabricating semiconductor device

(75) Inventor: Wataru Hattori, Tokyo (JP)

Correspondence Address: YOUNG & THOMPSON, 745 SOUTH 23RD STREET, 2ND FLOOR, ARLINGTON, VA, 22202, US

(73) Assignee: NEC CORPORATION, TOKYO (JP)

(21) Appl. No.: 10/501,762

(22) PCT Filed: Jan. 17, 2003
(86) PCT No.: PCT/JP03/00362

(30) Foreign Application Priority Data
Jan. 17, 2002 (JP) 2002-8501

(51) Int. Cl. H01L 21/00

(52) U.S. Cl. 438/34

(57) ABSTRACT

A template 3 manufactured to have high-accuracy protrusions and recesses in advance by a lithography technology employing an electron beam is pressed against a resist film 2 applied onto a substrate 1 thus transferring a resist pattern 5. A thin metal film 6 foe electrode s then formed on the resist pattern 5 formed by transfer and then it is stripped off by a lift-off method along with the resist film 2.

### TECHNICAL FIELD

This invention relates to a method of manufacturing a surface acoustic wave device and a semiconductor device. More specifically, this invention relates to a method which enables mass-production, at low cost, of a device which realizes the precisely stable usable frequency and usable wavelength even in the high radio-frequency region or in the short-wavelength region.

### BACKGROUND ART

A surface acoustic wave device generates the surface acoustic wave on the surface of a substrate by a lattice-formed electrode formed on a piezoelectric substrate. In a radio-communication field, the device is widely used as a band filter or a resonator. Especially, when the device is used as a band-pass filter, it is small in size and can realize the rapid out-of-band removal characteristic as compared to a dielectric filter or a stacked LC filter. Therefore, the surface acoustic wave device is mainly used as a band-pass filter to be used in cellular phones. Today, the device is used not only in the electric and communication fields but also in the various fields including biochemistry to be used as the device to arrange DNA or a sensor.

The surface acoustic wave device used in the radio-communication field has a lattice-formed electrode for generating the acoustic surface wave on the surface of the piezoelectric substrate. The width of the lattice-formed electrode depends on the wavelength which is determined by the usable frequency. For example, in case where the surface acoustic wave device is used as a resonator, the width of the lattice-formed electrode is set to the value of ¼ of the wavelength which is obtained by removing the acoustic velocity of the surface acoustic wave by the resonance frequency of the resonator. The recent development of the photolithography technique using the usual light enables the production of the device having the electrode width of 4 μm which applies to the frequency of 2.4 GHz band used in Bluetooth and wireless LAN in the wireless communication fields.

A lift-off method is well known as the method of forming fine electrode patterns on the surface acoustic wave device. In the lift-off method, at first a resist pattern is formed on the piezoelectric substrate by the photolithography technique using the usual light. Then a metal film is formed on a whole surface of the substrate. The metal electrode pattern is formed by pealing off the unnecessary metal film together with the resist. Alternatively, in a known method, after forming a metal film for the electrode is formed on the piezoelectric substrate, the resist pattern is formed by the photolithography technique using the usual light, and etching process is carried out for the metal film along with the resist pattern.

In recent years, the source of the frequency to be used is in the very tight situation but the radio-communication is becoming broad-banded. Followingly the frequency band of radio wave to be used in the communications is shifting to the high-frequency band. For example, the frequency band used in the wireless LAN used to be 2.4 GHz, however, it is becoming higher to 5 GHz band and even to 26 GHz band. The frequency band to be used by 4th generation mobile phone is assumed to be at the 5 GHz band or higher band. Accordingly, the surface acoustic wave device is required to realize high-performance which is appropriate for to be used in a high frequency or in the short-wavelength region.

As described above, the width of the lattice-formed electrode is determined by the usable frequency and the electrode width becomes narrower as the usable frequency becomes higher. Relating to the manufacture of the surface acoustic wave device having the narrower electrode width for use in the high-frequency band, a precise resist pattern should be formed to improve the gap between the electrode widths.

For example, when the surface acoustic wave device is manufactured by using LiTaO₃ substrate as a piezoelectric substrate, it is necessary to have the highly precise resist pattern which can realize the electrode width less than 0.4 μm and within the error range of 1% or less because the wavelength of the surface acoustic wave device becomes shorter as the frequency becomes higher. It is difficult to manufacture such precise resist pattern by the conventional photolithography technique using the usual light. Even if the substrate of other material, such as LiNbO₃ substrate, crystal substrate, a diamond thin-film substrate or ZnO thin film substrate is used as a piezoelectric substrate, the electrode width does not differ in size as compared with the above-mentioned electrode width. Therefore, the photolithography method using the usual light has already reached its limit for the application.

On the other hand, as the technique to form the fine and highly precise resist pattern, a lithography technique of irradiating the resist pattern by the use of electronic beam is known. In this method, it is possible to realize the electrode width of equal to or smaller than 0.4 μm at the accurate degree of 1 nano-meter order. However, the method of exposing the resist pattern by the beam-exposure has the problem such that the throughput is low as compared with the photolithography technique which can carry out the expose all at once. Moreover, as the pattern is highly precise, the error may be occurred to the lithography pattern on each substrate with time due to the thermal expansion or contraction of the substrate which is caused by the change of the outside air temperature. This leads to the problems in the mass production.

The object of the present invention is to solve the above-described problems in the conventional technique and to provide a method of manufacturing the surface acoustic wave device and the semiconductor device which can be mass-produced at a low cost, the device which can realize precise stable usable frequency or usable wavelength even in the high radio-frequency region or in the short-wavelength region.

### DISCLOSURE OF THE INVENTION

A method of manufacturing a surface acoustic wave device according to the present invention comprises the steps of applying a resist onto a piezoelectric substrate, forming a resist groove pattern by pressing a template which has a desirable recess and protrusion patterns on the surface thereof against the resist on the piezoelectric substrate, and forming an electrode film pattern

According to the present invention, in the step of forming the resist pattern, a pattern having the desirable recesses and protrusions are formed on the resist film by pressing the template on the surface of the resist film. In this way, the exposure step using the light or electronic beam is not necessary. Also, as the pattern can be transferred all at once to the resist by just pressing the template, it is possible to manufacture the surface acoustic wave device having the high dimension accuracy with high throughput.

A method of manufacturing the semiconductor device according to the present invention comprises the steps of applying a resist onto a substrate, forming a resist groove pattern by pressing a template which has a desirable recess and protrusion patterns on the surface thereof against the resist on the substrate.

By employing the step of patterning the resist by the use of the template, a pattern having the high dimension accuracy can be formed with high throughput.

In a method of manufacturing the surface acoustic wave device according to the present invention, a step of forming the electrode film pattern comprises the steps of depositing an electrode film and a lift-off step for removing a part of the electrode film together with the resist groove pattern.

The step of depositing the electrode film can be carried out previously to the step of applying the resist and the electrode film can be patterned in the step of forming the electrode film pattern.

In a method of manufacturing the surface acoustic wave device according to the present invention, the recess and protrusion pattern is preferably formed on the template by the lithography technique using the electronic beam exposure.

By employing the lithography technique using the electronic beam exposure for a method of manufacturing the template, a pattern can be formed at nano-meter order accuracy. Moreover, by reusing the template, the tracing pattern formed by the electronic beam exposure for each substrate will not be changed with time even by the change of the outside air temperature.

The template is preferably formed of at least one material selected from a group containing silicon, a silicon dioxide film, silicon glass, a sapphire, sapphire glass, polymeric resin, invar, or kovar.

More specifically, the preferable material for forming the template is silicon or silicon dioxide film which are efficient in fine processing, quartz such as silicon glass, a sapphire or sapphire glass which is hard and has low coefficient of thermal expansion, polymeric resin which can be easily processed or, if metallic material is to be used, invar or kovar which has low coefficient of thermal expansion.

In a method of manufacturing the surface acoustic wave device, it is preferable to form, on the surface of the template, an organic polymer thin film having the hydrophobic group. In this way, the template is easily be peeled off from the resist.

In a method of forming a surface acoustic wave device, succeeding to the step of forming the resist groove pattern, it is preferable to have the step of ashing the resist groove pattern. Herein, by removing the remaining resist in the recess portion, it is possible to prevent the metal film for electrode to be peeled off.

In a method of manufacturing the surface acoustic wave device, it is preferable that the electrode width of the electrode film pattern is equal to or less than 4 μm.

The method according to the present invention is more effective when applied to manufacture of the surface acoustic wave device for which the main usable frequency is equal to or higher than 2.5 GHz or the main usable wavelength of the surface acoustic wave is less than 1.6 μm.

### BRIEF DESCRIPTION OF THE DRAWING

FIG. 1 is a flowchart showing the step of manufacturing method of a surface acoustic wave device according to one embodiment of the present invention.

FIGS. 2A through 2F are view for showing the process of manufacture of the surface acoustic wave device shown in FIG. 1.

### BEST MODE FOR CARRYING OUT THE INVENTION

Hereinbelow, description will be made in more detail with reference to the drawings.

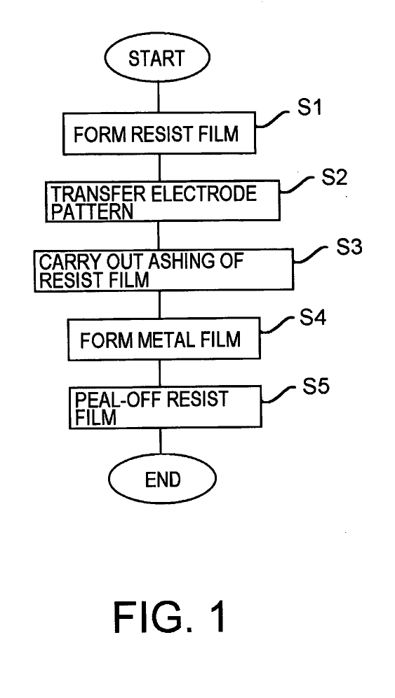

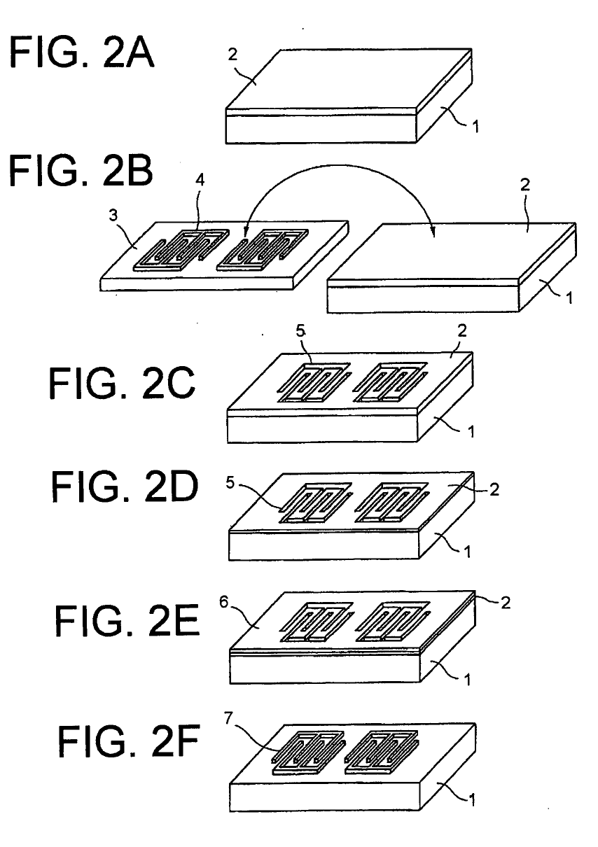

Referring to FIG. 1 and FIGS. 2A through 2F, description will be made about the method of manufacturing a surface acoustic wave device.

Referring to FIG. 2A, a flat resist film 2 is formed on a piezoelectric substrate 1 by spin-coat method (step S1). As the piezoelectric substrate 1, the piezoelectric substrate made of LiTiO₃, LiNbO₃ or a crystal, a substrate having an insulating film formed thereon, a substrate made of ceramic piezoelectric body such as PZT or PLZT, or a substrate made of depositing a thin film such as a diamond thin film or a ZnO thin film layered on a substrate can be used.

Referring to FIG. 2B, a template 3 having a lattice-formed fin electrode pattern 4 formed thereon is pressed against the substrate 1. Thus, as shown in FIG. 2C, the lattice-formed fine electrode pattern 4 on the template 3 is transferred on a resist film 2 so as to form a desirable resist pattern 5 (step S2). When pressing the template 3 to the resist film 2, it is preferable to control the temperature of the substrate such that the temperature of the substrate is higher than the glass transferring temperature of the resist film 2. Thus the pressure upon transferring the pattern can be made small. It is also preferable to manufacture the template 3 by the highly precise lithography technique using the electrode beam exposure.

As a material for the template 3, silicon or silicon dioxide film on the silicon substrate is preferably used to make the fine processing easy. A quartz material such as silicon glass, a sapphire, or a sapphire glass which is hard and which has the small thermal expansion is also preferable to effectively ease the control condition of the temperature when transferring the pattern. In case where the temperate made of the material clear to the invisible light, it is easy to match with the substrate. As a material for the template, a polymeric resin which is easy to process can also be used. Because the control condition of the temperature is effectively eased in the method, it is preferable to use, as a metallic material, Invar or Kovar which has the low coefficient of the thermal expansion. Moreover, it is preferable to form an organic polymer thin film having hydrophobic group on a surface of the template 3 such that the template 3 can be easily removed from the resist 2. Herein, the organic polymer thin film is preferable to have the thickness which does not affect the pattern accuracy.

Next, an ashing or an anisotropy dry-etching process is carried out for the whole of the resist film 4 shown in FIG. 2C so as to remove the resist remaining in the recess (grooves) of the resist pattern 5 (step S3). By this step, as shown in FIG. 2D, the surface of the piezoelectric substrate 1 is exposed in the recess portion of the resist pattern 5.

Next as shown in FIG. 2E, a metal film 6 for an electrode is formed by sputtering (step S4).

Thereafter, by a lift-off method, the resist film 2 together with the metal film 6 formed thereon is peeled off and, as shown in FIG. 2F, the fine electrode pattern 7 is formed on the piezoelectric substrate 1 (step S5).

The width of the electrode pattern 7 should match the value ¼ of the wavelength λ which is computed from the usual usable frequency By minutely measuring and selecting the pattern of the template 3, even for the electrode width of less than 0.4 μm, the accurary of 1 nano-meter order can be achieved.

The surface acoustic wave device thus manufactured is separated into individual chip by dicing, and then be packaged. As the pattern can be transferred to the resist film on the substrate all at once, the throughput during the electrode forming step is high and is applicable to the mass production. Thus the device having the stable frequency and wavelength even in the high radio-frequency region or in the short-wavelength region at low cost.

In the above-described embodiment, the description has been made with the example of the lift-off method, however, the method of manufacturing the surface acoustic wave device of the present invention is not limited to the above description. For example, the electrode film may be deposited previously to the step of applying the resist and, after forming the resist pattern by patterning the resist film, the etching may be carried out for the electrode film using the resist pattern as a mask.

While this invention has thus been described in conjunction with preferred embodiments thereof, however, the method of manufacturing the surface acoustic device and the semiconductor device according to the present invention is not limited to the above-described embodiments. The method of manufacturing the surface acoustic wave device and the semiconductor device to which the various modifications and changes are made to the above-described embodiments are contained within the scope of the present invention.

Industrial Applicability

In the method of manufacturing the surface acoustic wave device and the semiconductor substrate, an accurate template is prepared in advance and the template is pressed to the resist film applied on the substrate so as to form the resist film into the resist pattern having the desirable recess and protrusion. Thus the device having highly stable usable frequency or usable wavelength even in the high radio-frequency region or a short-wavelength region can mass-produced at low cost.

1. A method of manufacturing a surface acoustic wave device having a resist applied on a piezoelectric substrate,
a template having a desirable recess and protrusion patterns formed on the surface thereof is pressed to the resist on the piezoelectric substrate so as to form the resist groove pattern, and
an electrode film pattern is formed based on the resist groove pattern.

2. A method of manufacturing a surface acoustic wave device as claimed in claim 1, wherein the electrode film pattern is formed by depositing the electrode film and then removing a part of the electrode film together with the resist groove pattern by lift-off method.

3. A method of manufacturing a surface acoustic wave device as claimed in claim 1, wherein the electrode is deposited previously to the applying of the resist, and
the electrode film pattern is formed by patterning the electrode film.

4. A method of manufacturing a surface acoustic wave device as claimed in claim 1, wherein the template is made of at least one material selected from a group containing silicon, silicon dioxide film, silicon glass, a sapphire, sapphire glass, polymeric resin, invar and kovar.

5. A method of manufacturing a surface acoustic wave device as claimed in claim 1, wherein the recess and protrusion pattern is formed on the template by lithography using the electronic beam exposure.

6. A method of manufacturing a surface acoustic wave device as claimed in claim 1, wherein an organic polymer thin film having a hydrophobic group is formed on the surface of the template.

7. A method of manufacturing a surface acoustic wave device as claimed in claim 1 wherein, after forming the resist groove pattern, an ashing process is carried out for the resist groove pattern.

8. A method of manufacturing a surface acoustic wave device as claimed in claim 1, wherein the electrode width of the electrode film pattern is less than 0.4 μm.

9. (canceled)
